(19) United States
(12) Patent Application Publication
(10) Pub. No.: US 2014/0160847 A1
(43) Pub. Date: Jun. 12, 2014

(54) NONVOLATILE MEMORY DEVICE AND MEMORY SYSTEM COMPRISING SAME

(71) Applicant: DONGHUN KWAK, HWASEONG-SI (KR)

(72) Inventor: DONGHUN KWAK, HWASEONG-SI (KR)

(21) Appl. No.: 14/088,502

(22) Filed: Nov. 25, 2013

(30) Foreign Application Priority Data
Dec. 11, 2012 (KR) 10-2012-0143720

(51) Int. Cl. G11C 16/08

(52) U.S. Cl. CPC G11C 16/08
USPC 365/185.11

(57) ABSTRACT

A nonvolatile memory device comprises a 3D memory cell array comprising multiple mats corresponding to different bit lines, each of the mats comprising multiple memory blocks, each of the memory blocks comprising multiple cell strings disposed perpendicular to a substrate and multiple string selection lines configured to select or unselect the cell strings, and each of the cell strings comprising at least one ground selection transistor, multiple memory cells, and at least one string selection transistor stacked in a direction perpendicular to the substrate. The nonvolatile memory device further comprises a string selection controller electrically connected to the mats through the string selection lines and configured to provide multiple string selection signals respectively corresponding to the string selection lines. Each of the string selection lines is connected with only one of the mats and the string selection signals are controlled independent from one another to independently select or unselect cell strings of different mats.

### CROSS-REFERENCE TO RELATED APPLICATIONS

This application claims priority under 35 U.S.C. §119 to Korean Patent Application No. 10-2012-00143720 filed on Dec. 11, 2012, the subject matter of which is hereby incorporated by reference.

### BACKGROUND OF THE INVENTION

The inventive concept relates generally to semiconductor memory devices, and more particularly to nonvolatile memory devices having memory cells arranged in a three-dimensional (3D) array.

Semiconductor devices can be roughly divided into two categories according to whether they retain stored data when disconnected from power. These categories include volatile memory devices, which lose stored data when disconnected from power, and nonvolatile memory devices, which retain stored data when disconnected from power. Examples of volatile memory devices include dynamic random access memory (DRAM) and static random access memory (SRAM). Examples of nonvolatile semiconductor memory devices include masked read-only memory (MROM), programmable ROM (PROM), erasable programmable ROM (EPROM), and electrically erasable programmable ROM (EEPROM).

Flash memory is a popular form of EEPROM that can be found in a wide variety of modern electronic devices. For example, flash memory is commonly used to store data and/or code in devices such as computers, cellular phones, personal digital assistants (PDAs), digital cameras, voice recorders, handheld personal computers (PCs), gaming consoles, facsimile machines, scanners, and printers, to name but a few.

In an effort to improve integration density and performance of flash memory devices, researchers have recently developed flash memory devices in which memory cells are stacked in a 3D array. The development of these flash memory devices, however, has presented numerous technical challenges related to device reliability. For instance, in a 3D array, it may be difficult to ensure structural integrity of each memory block, which can lead to defective performance. Consequently, there is a general need for new techniques and technologies to improve the reliability of flash memory and other forms of nonvolatile memory in which memory cells are arranged in a 3D array.

### SUMMARY OF THE INVENTION

In one embodiment of the inventive concept, a nonvolatile memory device comprises a 3D memory cell array comprising multiple mats corresponding to different bit lines, each of the mats comprising multiple memory blocks, each of the memory blocks comprising multiple cell strings disposed perpendicular to a substrate and multiple string selection lines configured to select or unselect the cell strings, and each of the cell strings comprising at least one ground selection transistor, multiple memory cells, and at least one string selection transistor stacked in a direction perpendicular to the substrate. The nonvolatile memory device further comprises a string selection controller electrically connected to the mats through the string selection lines and configured to provide multiple string selection signals respectively corresponding to the string selection lines. Each of the string selection lines is connected with only one of the mats and the string selection signals are controlled independent from one another to independently select or unselect cell strings of different mats.

In another embodiment of the inventive concept, a memory system comprises a nonvolatile memory device comprising a 3D memory cell array including multiple mats corresponding to different bit lines, each of the mats comprising multiple memory blocks, each of the memory blocks comprising multiple cell strings disposed perpendicular to a substrate and multiple string selection lines configured to select or unselect the cell strings. The memory system further comprises a memory controller configured to control the nonvolatile memory device such that at least one of the cell strings is independently selected or unselected through multiple string selection lines corresponding to the cell strings. Each of the string selection lines is connected with only one of the mats and the string selection signals are controlled independently from one another to independently select or unselect cell strings of different mats.

In still another embodiment of the inventive concept, a nonvolatile memory device comprises a 3D memory cell array comprising multiple mats corresponding to different bit lines, each of the mats comprising multiple memory blocks each comprising multiple cell strings disposed perpendicular to a substrate, and at least one string selection line or ground selection line configured to select or unselect the cell strings, and each of the cell strings comprising at least one ground selection transistor, multiple memory cells, and at least one string selection transistor stacked in a direction perpendicular to the substrate, the memory cell array further comprising a plurality of word lines connected in common to cell strings of different mats. The nonvolatile memory device further comprises a string selection controller electrically connected to the mats through the string selection lines or the ground selection lines and configured to provide multiple string selection signals respectively corresponding to the string selection lines or ground selection lines. Each of the string selection lines or ground selection lines is connected with only one of the mats and the string selection signals are controlled independent from one another to independently select or unselect cell strings of different mats, and wherein the word lines connected in common to the cells strings of different mats are configured to concurrently select memory cells in the different mats.

These and other embodiments of the inventive concept can potentially improve the reliability of 3D nonvolatile memory devices by reducing the number of memory cells affected by a defective sting selection line.

### BRIEF DESCRIPTION OF THE DRAWINGS

The drawings illustrate selected embodiments of the inventive concept. In the drawings, like reference numbers indicate like features.

FIG. 1 is a block diagram illustrating a nonvolatile memory device, according to an embodiment of the inventive concept.

FIG. 2 is a block diagram illustrating a memory cell array in FIG. 1, according to an embodiment of the inventive concept.

FIG. 3 is a perspective view of one memory block in a cell array of FIG. 1, according to an embodiment of the inventive concept.

FIG. 4 is a circuit diagram illustrating a cell string selection structure of a nonvolatile memory device, according to an embodiment of the inventive concept.

FIG. 5 is a block diagram illustrating a nonvolatile memory device, according to an embodiment of the inventive concept.

FIG. 6 is a circuit diagram illustrating a cell string selecting method of a string selection controller of FIG. 5, according to an embodiment of the inventive concept.

FIG. 7 is a block diagram illustrating a string selection controller, according to an embodiment of the inventive concept.

FIG. 8 is a block diagram illustrating a nonvolatile memory device, according to another embodiment of the inventive concept.

FIG. 9 is a block diagram illustrating a nonvolatile memory device, according to still another embodiment of the inventive concept.

FIG. 10 is a block diagram illustrating a string selection controller, according to another embodiment of the inventive concept.

FIG. 11 is a block diagram illustrating a control method for a nonvolatile memory device in which a string selection controller selects a normal cell string rather than a defective cell string, according to an embodiment of the inventive concept.

FIG. 12 is a block diagram illustrating a solid state drive (SSD), according to an embodiment of the inventive concept.

FIG. 13 is a block diagram illustrating a data storage device, according to an embodiment of the inventive concept.

FIG. 14 is a block diagram illustrating a memory card, according to an embodiment of the inventive concept.

FIG. 15 is a block diagram illustrating a computing system comprising a memory system, according to an embodiment of the inventive concept.

### DETAILED DESCRIPTION

Embodiments of the inventive concept are described below with reference to the accompanying drawings. These embodiments are presented as teaching examples and should not be construed to limit the scope of the inventive concept.

In the description that follows, the terms “first”, “second”, “third”, etc., may be used to describe various features, but the described features should not be limited by these terms. Rather, these terms are only used to distinguish between different features. Thus, a first feature discussed below could be termed a second feature and vice versa without materially changing the relevant teachings.

Spatially relative terms, such as “beneath”, “below”, “lower”, “under”, “above”, “upper” and the like, may be used herein for ease of description to describe one feature's relationship to another feature(s). The spatially relative terms are intended to encompass different orientations of the device in use or operation in addition to those depicted in the figures. For example, if a device in the figures is turned over, features described as “below” or “beneath” or “under” other features would then be oriented “above” the other features. Thus, the terms “below” and “under” can encompass both an orientation of above and below. The device may be otherwise oriented (rotated 90 degrees or at other orientations) and the spatially relative descriptors used herein interpreted accordingly. In addition, where a feature is referred to as being “between” two features, it can be the only feature between the two features, or one or more intervening features may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. Terms such as “comprises” and/or “comprising,” where used in this specification, indicate the presence of stated features but do not preclude the presence or addition of one or more other features. As used herein, the term “and/or” indicates any and all combinations of one or more of the associated listed items.

Where a feature is referred to as being “on”, “connected to”, “coupled to”, or “adjacent to” another feature, it can be directly on, connected, coupled, or adjacent to the other feature, or intervening features may be present. In contrast, where a feature is referred to as being “directly on,” “directly connected to”, “directly coupled to”, or “immediately adjacent to” another feature, there are no intervening features present.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

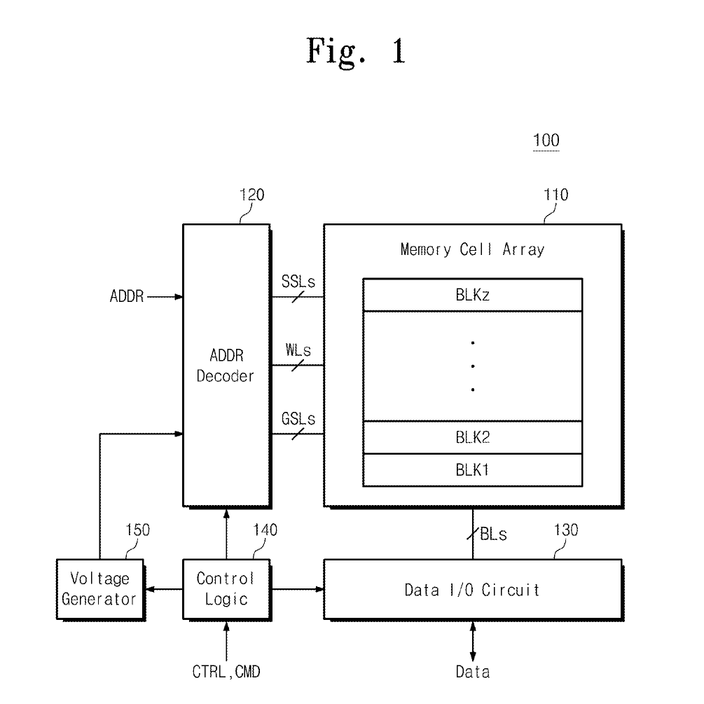

FIG. 1 is a block diagram illustrating a nonvolatile memory device where memory cells are stacked in a 3D array, according to an embodiment of the inventive concept.

Referring to FIG. 1, a nonvolatile memory device 100 comprises a memory cell array 110, an address decoder 120, a data input/output circuit 130, control logic 140, and a voltage generator 150.

Memory cell array 110 is connected to address decoder 120 via word lines WL and to data input/output circuit 130 via bit lines BL. Memory cell array 110 comprises multiple memory blocks and multiple mats. Each of the mats encompasses multiple memory blocks BLK1 to BLKz, and each of the memory blocks comprises multiple NAND cell strings. In some embodiments, the NAND cell strings are selected using multiple string selection lines SSLs and multiple ground selection lines GSLs.

A channel of each NAND cell string is formed in a vertical direction. In memory cell array 110, multiple word lines are stacked in a vertical direction, and a channel of each NAND cell string is formed in a vertical direction. A memory device comprising memory cell array 110 having the above-described cell string structure may be referred to as a vertical structure nonvolatile memory device or a 3D structure nonvolatile memory device. Each of the cell strings comprises at least one ground selection transistor, multiple memory cells, and at least one string selection transistor which are stacked in a direction perpendicular to a substrate. Each of memory cells in memory cell array 110 may be a single-level cell or a multi-level cell.

Voltage generator 150 generates voltages to be provided to address decoder 120 under control of control logic 140. For example, in a program operation, voltage generator 150 generates word line voltages such as a program voltage, a pass voltage, a program verification voltage, etc. under control of control logic 140. The word line voltages are provided to address decoder 120. In a read operation, voltage generator 150 generates word line voltages such as a selection read voltage, a non-selection read voltage, etc. under control of control logic 140. The word line voltages are provided to address decoder 120. Address decoder 120 selectively applies the word line voltages to word lines under control of control logic 140.

Address decoder 120 selects at least one page of memory cell array 110 in response to an address ADDR from an external source and a control of control logic 140. Address decoder 120 provides a selected page with a word line voltage from voltage generator 150.

For example, address decoder 120 may select one of memory blocks of memory cell array 110 in response to address ADDR. Address decoder 120 selects a string selection line of the selected memory block in response to address ADDR. Address decoder 120 selects a word line in response to address ADDR. A page is selected by selecting a string selection line and a word line.

In a program operation, address decoder 120 selects a page to provide the program voltage and the program verification voltage to a selected word line corresponding to the selected page. Address decoder 120 provides the pass voltage to unselected word lines.

In a read operation, address decoder 120 selects a page to provide the selection read voltage to a selected word line corresponding to the selected page. Address decoder 120 provides the non-selection read voltage to unselected word lines.

Data input/output circuit 130 receives data from an external source and stores it in memory cell array 110. Data input/output circuit 130 reads data stored in memory cell array 110 and outputs it to an external destination. Data input/output circuit 130 may comprise, for instance, a column selecting gate, a page buffer, a write driver, a sense amplifier, a data buffer, and so on.

Control logic 140 controls overall operations of nonvolatile memory device 100 in response to a command CMD and a control signal CTRL from an external source. For example, control logic 140 may control a program operation of nonvolatile memory device 100 in response to a program command CMD from an external source. Control logic 140 controls a read operation of nonvolatile memory device 100 in response to a read command CMD from an external source.

In some embodiments, nonvolatile memory device 100 independently selects at least one cell string through a string selection line that is exclusively connected with a mat. In some other embodiments, nonvolatile memory device 100 independently selects at least one cell string through a ground selection line that is exclusively connected with a mat. In the description that follows, it will be assumed for the sake of convenience that the independent selection of cell strings is performed by the string selection line, but the ground selection line could be used alternatively.

In a nonvolatile memory device where a string selection line or ground selection line is connected to multiple mats, all of the mats may be affected by a defect in the string selection line or ground selection line. However, where a string selection line or ground selection line is exclusively connected with only one mat, other mats may be unaffected by a defect in the string selection line or ground selection line.

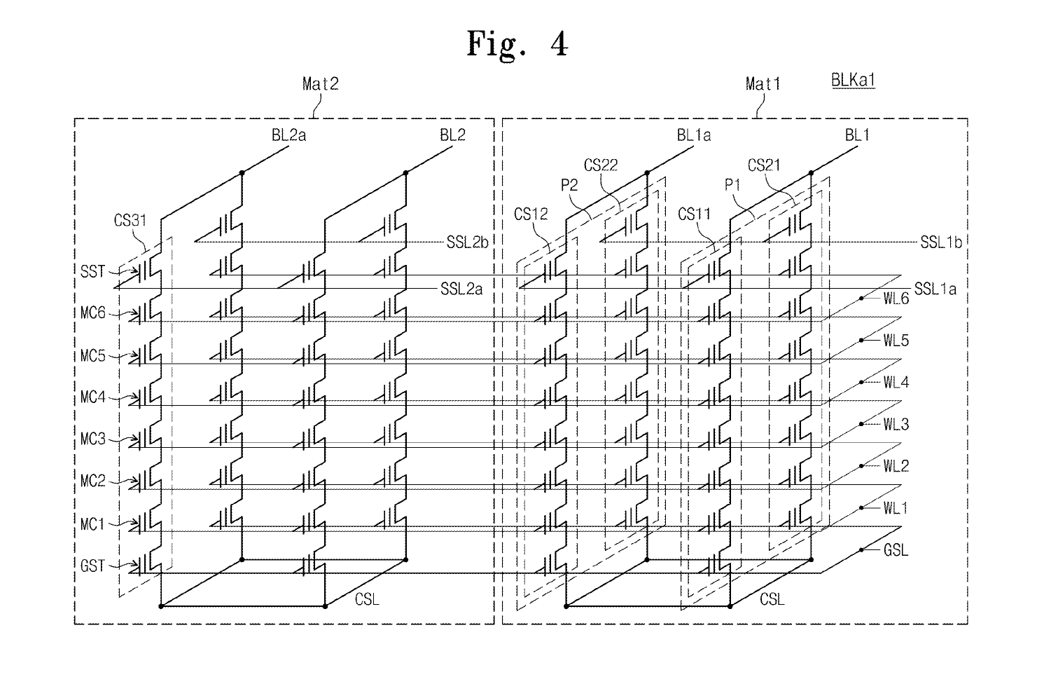

Nonvolatile memory device 100 applies a selection voltage to a string selection line such that at least one cell string corresponding to the string selection line is independently selected. Alternatively, nonvolatile memory device 100 may apply a non-selection voltage to a string selection line such that at least one cell string corresponding to the string selection line is independently unselected. This will be more fully described with reference to FIG. 4.

As described above, cell strings may be selected by a string selection line exclusively connected with one mat. With this architecture, where a string selection line is defective, performance of the mat connected with a defective string selection line may be lowered. Thus, cell strings in other mats may be normally selected such that the number of cell strings affected by the defective string selection line is reduced.

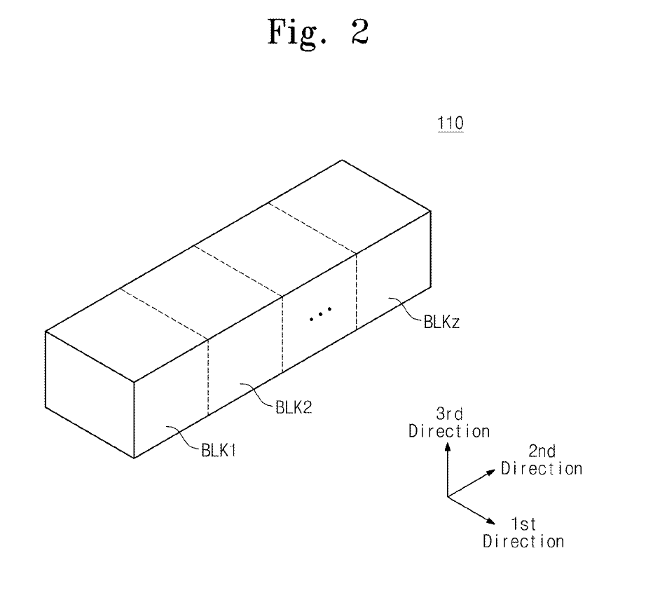

FIG. 2 is a block diagram illustrating an example of memory cell array 110 of FIG. 1, according to an embodiment of the inventive concept.

Referring to FIG. 2, memory cell array 110 comprises multiple memory blocks BLK1 to BLKz each formed with a 3D structure (or, a vertical structure). For example, each of memory blocks BLK1 to BLKz may include structures extending along first to third directions. Although not shown in FIG. 2, each of memory blocks BLK1 to BLKz may comprise multiple cell strings extending along the second direction, and multiple cell strings may be spaced apart from one another along the first and third directions.

Cell strings (not shown) in one memory block may be coupled with multiple bit lines, multiple string selection lines, multiple word lines, one or more ground selection lines, and a common source line. Cell strings in memory blocks BLK1 to BLKz may share the bit lines. For example, the bit lines may extend along the second direction so as to be shared by memory blocks BLK1 to BLKz.

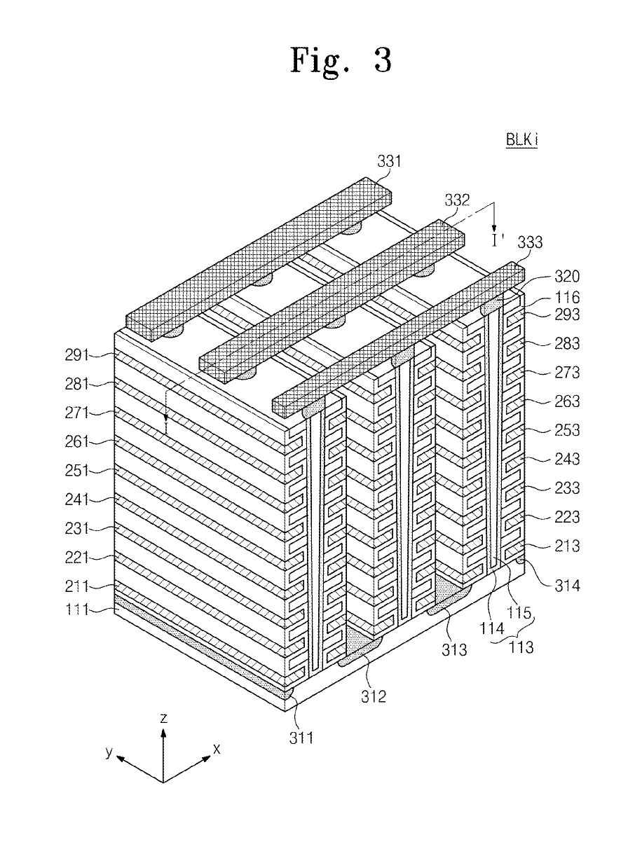

Memory blocks BLK1 to BLKz are selected by address decoder 120 in FIG. 1. For example, address decoder 120 is typically configured to select a memory block, corresponding to an input address ADDR, from among memory blocks BLK1 to BLKz. Erasing, programming, and reading may be performed with respect to the selected memory block. Memory blocks BLK1 to BLKz will be more fully described with reference to FIGS. 3 and 4.

FIG. 3 is a perspective view of one memory block in memory cell array 110 of FIG. 1, according to an embodiment of the inventive concept.

Referring to FIG. 3, a memory block BLKi comprises cell strings formed in a 3D structure or a vertical structure. Memory block BLKi comprises structures extending along multiple directions x, y, and z.

First, a substrate 111 is provided to form memory block BLKi. For example, substrate 111 may be formed of a p-well injected with a Group IV element such as boron. As an example, substrate 111 may be a pocket p-well provided in an n-well. Hereinafter, it is assumed that substrate 111 is a p-well, although substrate 111 is not limited thereto.

Multiple doping regions 311 to 314 extending in the x-direction are provided in substrate 111. For example, doping regions 311 to 314 may be n-type, respectively. Hereinafter, it is assumed that first to fourth doping regions 311 to 314 are n-type, although first to fourth doping regions 311 to 314 are not limited thereto.

On substrate 111 between first and second doping regions 311 and 312, multiple insulating materials 112 extending along the y-direction are sequentially provided along the z-direction. For example, insulating materials 112 may be formed to be spaced apart along the z-direction. Insulating materials 112 typically comprise an insulating material such as silicon oxide.

On substrate 111 between first and second doping regions 311 and 312, multiple pillars 113 are provided which are sequentially disposed along the y-direction and pass through insulating materials 112 along the z-direction. Pillars 113 may be connected to substrate 111 through insulating materials 112, respectively. Herein, pillars 113 may be formed on substrate 111 between second and third doping regions 312 and 313 and on substrate 111 between third and fourth doping regions 313 and 314, respectively.

Each of pillars 113 can be formed of multiple materials. For example, a surface layer 114 of each pillar 113 may comprise a silicon material having a first type. For example, surface layer 114 of each pillar 113 may comprise a silicon material having the same type of doping as substrate 111. Hereinafter, it is assumed that surface layer 114 of each pillar 113 comprises p-type silicon, although surface layer 114 of each pillar 113 is not limited thereto.

An inner layer 115 of each pillar 113 typically comprises an insulating material such as silicon oxide, and it can also comprise an air gap.

Between first and second doping regions 311 and 312, an insulation layer 116 is provided along exposed surfaces of substrate 111, insulating materials 112, and pillars 113. An insulation layer 116 can be removed from a surface of last insulation material 112 exposed toward the z-direction.

Between first and second doping regions 311 and 312, first conductive materials 211 to 291 are provided to be formed on an exposed surface of insulation layer 116. For example, conductive material 211 extending along the y-direction may be provided between substrate 111 and insulating material 112 adjacent to substrate 111. More specifically, conductive material 211 extending along the x-direction may be provided between substrate 111 and insulation layer 116 on the lower surface of insulating material 112 adjacent to substrate 111.

The first conductive material extending along the y-direction may be provided between insulation layer 116 on an upper surface of a specific insulating material of insulating materials 112 and insulation layer 116 on a lower surface of an insulating material disposed on the upper portion of the specific insulating material. First conductive materials 221 to 281 extending along the y-direction are provided between insulating materials 112. First conductive materials 211 to 291 may be metal materials or other conductive materials such as polysilicon, for example.

The same structure as that between first and second doping regions 311 and 312 may be provided between second and third doping regions 312 and 313. Between second and third doping regions 312 and 313, for example, there may be provided insulating materials 112 extending along the y-direction, pillars 113 sequentially disposed along the y-direction and passing through insulating materials 112 along the z-direction, insulation layer 116 on and exposed surfaces of pillars 113 and insulating materials 112, and first conductive materials 212 to 292 extending along the y-direction.

The same structure as that between first and second doping regions 311 and 312 may be provided between third and fourth doping regions 313 and 314. Between third and fourth doping regions 313 and 314, for example, there may be insulating materials 112 extending along the y-direction, pillars 113 sequentially disposed along the y-direction and passing through insulating materials 112 along the z-direction, insulation layer 116 on and exposed surfaces of pillars 113 and insulating materials 112, and first conductive materials 213 to 293 extending along the y-direction.

Drains 320 may be provided on pillars 113, respectively. Second conductive materials 331 to 333 extending along the x-direction may be provided on drains 320. Second conductive materials 331 to 333 may be sequentially disposed along the y-direction. Second conductive materials 331 to 333 may be connected to drains 320 of corresponding regions, respectively. Drains 320 and second conductive material 333 extending along the x-direction may be connected through corresponding contact plugs. Second conductive materials 331 to 333 may be metal materials or other types of conductive materials such as polysilicon, for example.

FIG. 4 is a circuit diagram illustrating a cell string selection structure of a nonvolatile memory device, according to an embodiment of the inventive concept.

Referring to FIG. 4, the nonvolatile memory comprises a memory cell array organized into multiple mats Mat1 and Mat2 each comprising multiple memory blocks having multiple cell strings. For example, a memory block of first mat Matt comprises multiple cell strings CS11, CS12, CS21, and CS22. Multiple cell strings in a mat may be formed in multiple planes P1 and P2. Each of mats Mat1 and Mat2 comprises multiple memory blocks, and one of the memory blocks has multiple string selection lines SSL1a and SSL1b configured to select at least one of multiple cell strings CS11, CS12, CS21, and CS22. For example, where a selection voltage is applied to a first string selection line SSL1a, the first and second cell strings CS11 and CS12 may be selected. Where a selection voltage is applied to a second string selection line SSL1b, third and fourth cell strings CS21 and CS22 may be selected.

In some embodiments, first and second mats Mat1 and Mat2 have the same physical structure. For example, like first mat Mat1, second mat Mat2 may comprise multiple memory blocks and multiple cell strings formed in multiple planes. Also, second mat Mat2 may comprise multiple string selection lines SSL2a and SSL2b configured to select at least one of multiple cell strings.

First and second mats Mat1 and Mat2 share word lines and a common source line. For example, cell strings in first and second mats Mat1 and Mat2 are connected with the same word lines WL1 to WL6. On the other hand, first and second mats Mat1 and Mat2 do not share bit lines. For example, first bit lines BL1 and BL1a are only connected with first mat Mat1. Similarly, second bit lines BL2 and BL2a are only connected with second mat Mat2.

Although FIG. 4 illustrates an example in which each mat is connected with two bit lines and six word lines, the inventive concept is not limited to these features. For example, each mat can be connected with three or more bit lines and seven or more word lines.

Each cell string may include at least one string selection transistor, memory cells, and at least one ground selection transistor. For example, a cell string CS31 may include a ground selection transistor GST, multiple memory cells MC1 to MC6, and a string selection transistor SST sequentially being perpendicular to a substrate. The remaining cell strings may be formed substantially the same as the cell string CS31.

First and second mats Mat1 and Mat2 comprise independent string selection lines. For example, string selection lines SSL1a and SSL1b are only connected with first mat Mat1, and string selection lines SSL2a and SSL2b are only connected with the second mat Mat1. A string selection line may be used to select cell strings only in a mat. Also, cell strings may be independently selected every mat by controlling the string selection lines independently.

For example, cell strings CS 11 and CS 12 may be independently selected by applying a selection voltage only to first string selection line SSL1. Where the selection voltage is applied to first string selection line SSL1, string selection transistors of cell strings CS11 and CS12 corresponding to first string selection line SSL1 may be turned on by the selection voltage. At this time, memory cells of the cell strings CS11 and CS12 may be electrically connected with a bit line.

Where a non-selection voltage is applied to first string selection line SSL1, string selection transistors of cell strings CS11 and CS12 corresponding to first string selection line SSL1 are turned off by the non-selection voltage. At this time, memory cells of the cell strings CS11 and CS12 are electrically isolated from a bit line.

A structure where string selection lines are exclusively provided at mats may make it possible to minimize the influence of a defective string selection line. For example, suppose first and second mats Mat1 and Mat2 share a string selection line. Under these circumstances, if the shared string selection line is defective, such defect may influence all mats Mat 1 and Mat2. That is, cell strings connected with the defective string selection line may not operate normally. Also, the more the number mats connected with the defective string selection line, the more the number of cell strings not operating normally.

On the other hand, where string selection lines are separated according to each mat, a defect of a string selection line may influence only a mat including the defective string selection line. Thus, it is possible to reduce the number of cell strings affected by the defect.

Also, string selection lines independently provided at each mat may be used to select cell strings of each mat, independently. That is, cell strings in first mat Mat1 may be selected to be independent from cell strings in second mat Mat2. This independent selection structure may make it easy to control a nonvolatile memory device 100 (See, e.g., FIG. 1).

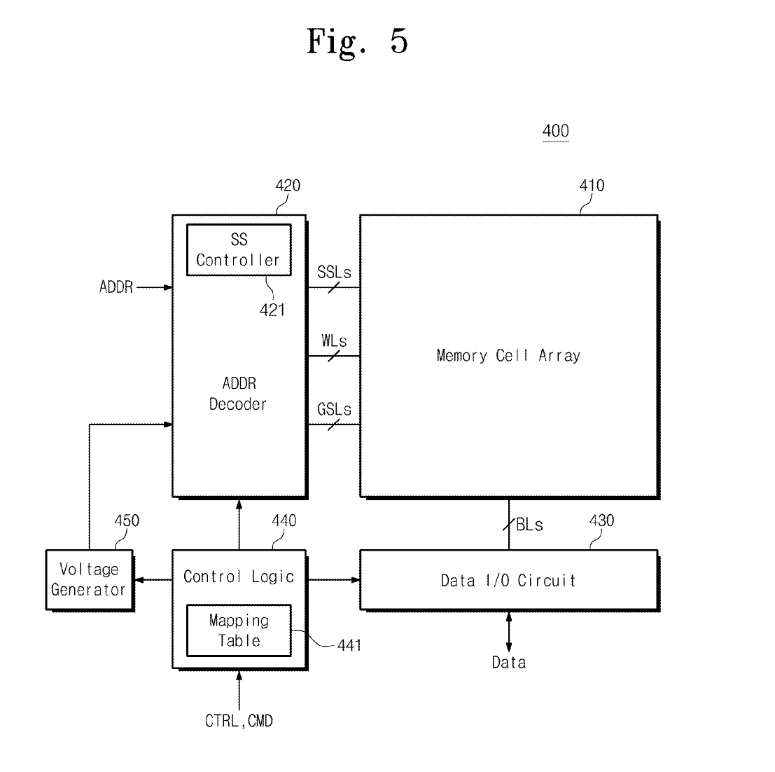

FIG. 5 is a block diagram illustrating a nonvolatile memory device, according to an embodiment of the inventive concept.

Referring to FIG. 5, a nonvolatile memory device 400 comprises a memory cell array 410, an address decoder 420, a data input/output circuit 430, control logic 440, and a voltage generator 450.

Address decoder 420 provides memory cell array 410 with word line voltages through word lines. Address decoder 420 controls ground selection transistors in a cell string of memory cell array 410 through ground selection lines GSLs. Address decoder 420 selects cell strings of memory cell array 410 through string selection lines SSLs.

Address decoder 420 comprises a string selection controller 421. String selection controller 421 controls string selection lines SSLs under control of control logic 440 or address decoder 420. Each of string selection lines SSLs may be independently connected to one of mats of memory cell array 410. String selection controller 421 controls memory cell array 410 through string selection lines SSLs such that cell strings are independently selected every mat.

String selection controller 421 selectively provides a selection voltage to string selection lines SSLs to select at least one cell string of memory cell array 410. For example, string selection controller 421 may provide the selection voltage to a string selection line, corresponding to a selected cell string, among string selection lines SSLs. A string selection transistor of the selected cell string may be turned on by the selection voltage applied to the string selection line, and memory cells in the selected cell string may be electrically connected to a corresponding bit line.

String selection controller 421 selectively provides a non-selection voltage to string selection lines SSLs to unselect at least one cell string of memory cell array 410. For example, string selection controller 421 may provide the non-selection voltage to a string selection line, corresponding to an unselected cell string, among string selection lines SSLs. A string selection transistor of the unselected cell string may be turned off by the non-selection voltage applied to the string selection line, and memory cells in the unselected cell string may be electrically disconnected from a corresponding bit line. In some embodiments, the selection or non-selection voltage applied to a string selection line is provided as a string selection signal.

Voltage generator 450 generates word line voltages and provides them to address decoder 420. In some embodiments, voltage generator 450 generates the selection voltage or the non-selection voltage to be provided to address decoder 420. The selection voltage or the non-selection voltage may be provided to string selection controller 421.

Control logic 440 may control overall operations of nonvolatile memory device 400 including string selection controller 421. When data is programmed in memory cell array 410, control logic 440 refers to a mapping table 441 comprising defect information of string selection lines. The defect information of string selection lines indicates a defective string selection line of multiple string selection lines. Where a defective string selection line is detected, control logic 440 controls string selection controller 421 such that another string selection line is selected rather than the defective string selection line.

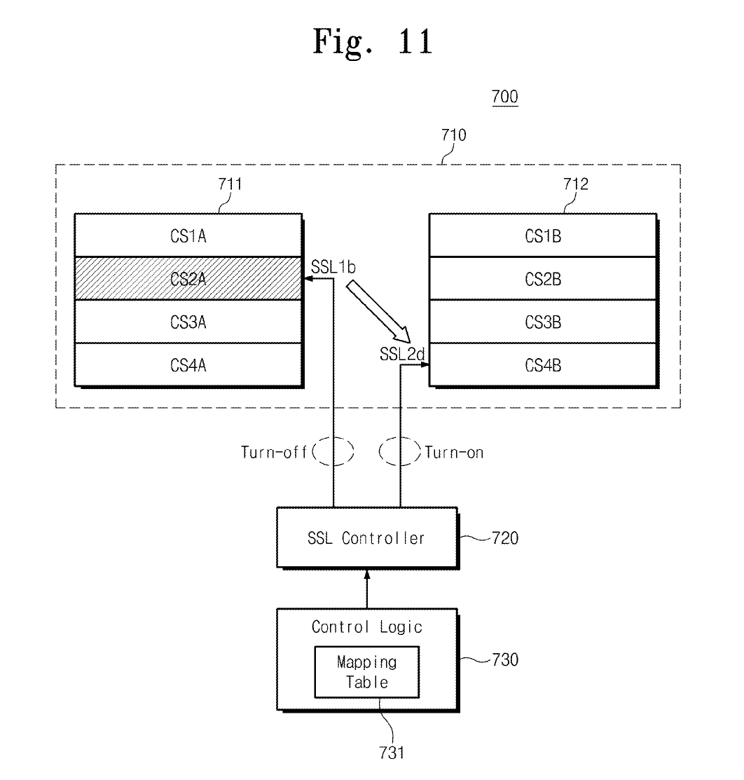

A method in which control logic 440 controls string selection controller 421 based on mapping table 441 will be more fully described with reference to FIG. 11.

In FIG. 5, components 410, 420, 430, 440, and 450 may operate substantially the same as those in FIG. 1.

As indicated by the above description, nonvolatile memory device 400 may select or unselect cell strings of memory cell array 410 independently for every mat using string selection controller 421. Where a string selection line is defective, only one mat may be influenced by the defective string selection line. Because cell strings in another mat are normally selected, the number of cell strings operating abnormally due to the defective string selection line may be reduced.

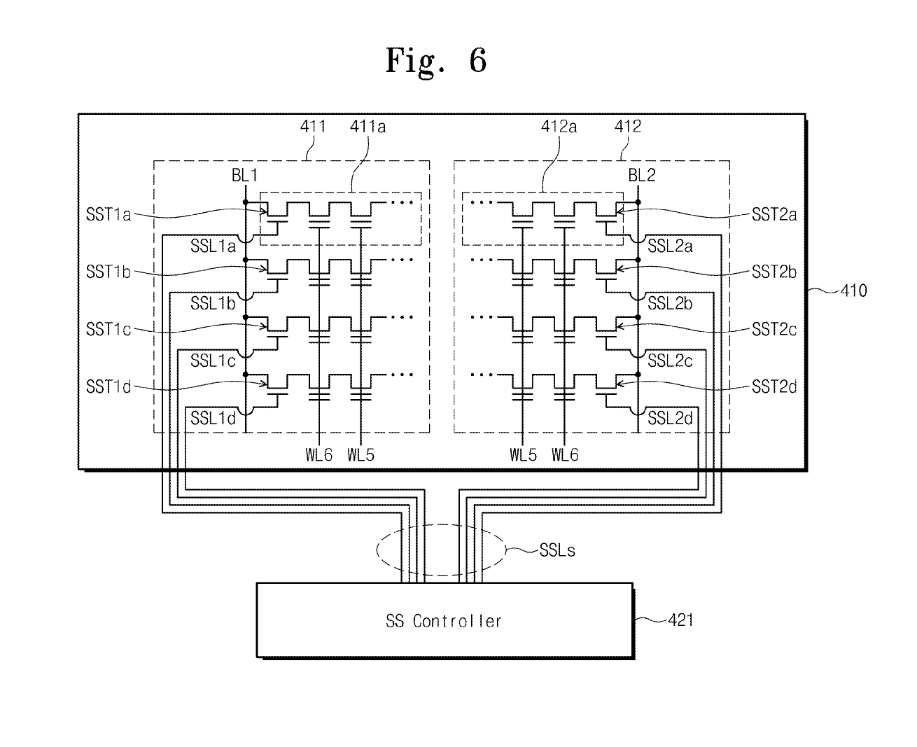

FIG. 6 is a circuit diagram illustrating a cell string selecting method of a string selection controller of FIG. 5, according to an embodiment of the inventive concept.

Referring to FIG. 6, string selection controller 421 selects or unselects cell strings of memory cell array 410 independently for every mat. Here, there is illustrated an example where a mat is connected with a bit line. However, the inventive concept is not limited thereto. For example, each mat may be connected with two or more bit lines. A structure of mats 411 and 412 of memory cell array 410 in FIG. 6 may be the same as that of mats Mat1 and Mat2 in FIG. 4.

Memory cell array 410 comprises first and second mats 411 and 412. Each of first and second mats 411 and 412 comprises multiple cell strings. Each cell string comprises at least one string selection transistor and multiple memory cells. For example, first mat 411 comprises multiple cell strings connected with a bit line BL1, and each cell string comprises string selection transistors SST1a, SST1b, SST1c, and SST1d for electrically connecting bit line BL1 with memory cells. String selection lines SSL1a, SSL1b, SSL1c, and SSL1d are connected to gates of the string selection transistors SST1a, SST1b, SST1c, and SST1d, respectively.

Similarly, second mat 412 may include multiple cell strings connected with a bit line BL2, and each cell string may include string selection transistors SST2a, SST2b, SST2c, and SST2d for electrically connecting bit line BL2 with memory cells. String selection lines SSL2a, SSL2b, SSL2c, and SSL2d are connected to gates of the string selection transistors SST2a, SST2b, SST2c, and SST2d, respectively.

First and second mats 411 and 412 share word lines WL5 and WL6. Here, there is illustrated an example where two word lines WL5 and WL6 are connected with each mat. However, the inventive concept is not limited thereto. For example, three or more word lines can be connected with each mat.

Contents of first and second mats 411 and 412 not described with reference to FIG. 6 may be equal to those described with reference to FIG. 4.

String selection controller 421 controls multiple string selection lines SSLs. String selection lines SSLs comprise multiple string selection lines SSL1a, SSL1b, SSL1c, SSL1d, SSL2a, SSL2b, SSL2c, and SSL2d corresponding to multiple string selection transistors SST1a, SST1b, SST1c, SST1d, SST2a, SST2b, SST2c, and SST2d.

String selection controller 421 independently controls string selection lines SSLs to select or unselect cell strings of first or second mat 411 or 412 independently for every mat. For example, string selection controller 421 may control multiple string selection signals provided to string selection lines SSLs so as to have a selection voltage or a non-selection voltage independently. The string selection signals may be applied to gates of string selection transistors SST1a, SST1b, SST1c, SST1d, SST2a, SST2b, SST2c, and SST2d through string selection lines SSL1a, SSL1b, SSL1c, SSL1d, SSL2a, SSL2b, SSL2c, and SSL2d, respectively. String selection transistors SST1a, SST1b, SST1c, SST1d, SST2a, SST2b, SST2c, and SST2d may be independently turned on or off according to whether an applied string selection signal has a selection voltage.

For example, to select a first cell string 411a in first mat 411, string selection controller 421 may provide a first string selection line SSL1a corresponding to first cell string 411a with a selection voltage as a string selection signal. At this time, first string selection line SSL1a may be connected to a gate of string selection transistor SST1a of first cell string 411a, and string selection transistor SST1a may be turned on by the string selection signal provided to first string selection line SSL1a. Where first string selection line SSL1a is turned on, first cell string 411a may be electrically connected to first bit line BL1. Here, first string selection line SSL1a may be only connected to first cell string 411a, and may not affect selection of other cell strings. That is, first cell string 411a may be selected independently from other cell strings by a control of first string selection line SSL1a.

Although FIG. 6 illustrates an example where one cell string is connected with a string selection line, the inventive concept is not limited thereto. For example, suppose that first mat 411 is connected with multiple bit lines and the first string selection line SSL1a is connected with two or more cell strings. Under these circumstances, if a selection voltage is applied to the first string selection line SSL1a as a selection voltage, two or more cell strings may be simultaneously selected. Similarly, the first string selection line SSL1a may be only connected with first mat 411. That is, two or more cell strings selected by the first string selection line SSL1a may be cell strings of first mat 411.

To select a second cell string 412a in second mat 412, string selection controller 421 may provide a second string selection line SSL2a corresponding to second cell string 412a with a selection voltage as a string selection signal. Second cell string 412a may be selected independently from other cell strings by a control of the second string selection line SSL2a.

With the above-described architecture, because cell strings in each mat are selected by different string selection lines, cell strings of one mat may be selected or unselected independently from cell strings of another mat.

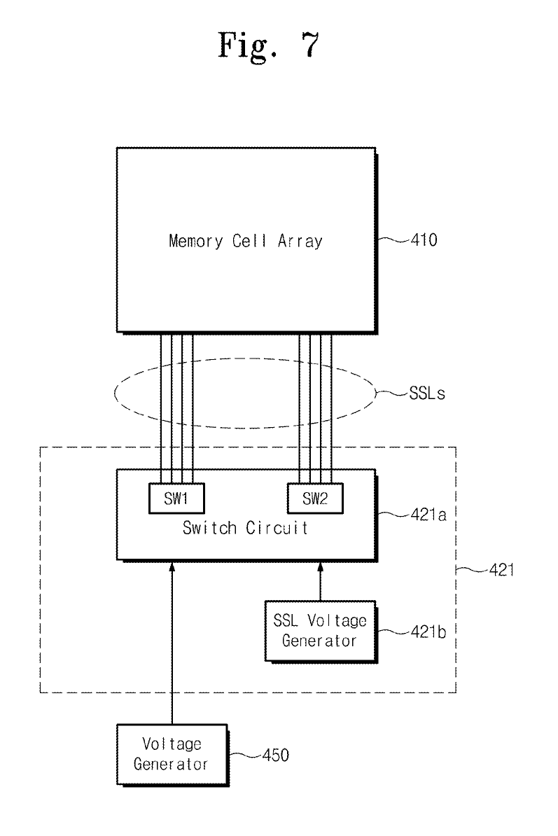

FIG. 7 is a block diagram illustrating a string selection controller according to an embodiment of the inventive concept.

Referring to FIG. 7, a string selection controller 421 comprises a switch circuit 421a and a string selection voltage generator 421b.

String selection voltage generator 421b generates a selection voltage or a non-selection voltage. Here, the selection voltage may have a voltage level (e.g., 6V) sufficient to turn on a string selection transistor of a cell string. A voltage level of the selection voltage may be a voltage level indicating a logic high level. The non-selection voltage may have a voltage level (e.g., 0V) sufficient to turn off a string selection transistor of a cell string. A voltage level of the non-selection voltage may be a voltage level indicating a logic low level.

Switch circuit 421a selectively provides the selection voltage or the non-selection voltage to string selection lines SSLs. In some embodiments, the selection voltage or the non-selection voltage may be provided as a string selection signal. In some embodiments, switch circuit 421a may be controlled by control logic 440 (See, e.g., FIG. 5) or an address decoder 420 (See, e.g., FIG. 5). Switch circuit 421a provides the selection voltage from string selection voltage generator 421b to a string selection line, connected with a selected cell string, from among string selection lines SSLs. Switch circuit 421a provides the non-selection voltage provided from string selection voltage generator 421b to a string selection line, connected with an unselected cell string, from among string selection lines SSLs.

In some embodiments, the respective string selection lines SSLs are exclusively connected with one mat. Thus, the selection voltage or the non-selection voltage provided through switch circuit 421a may enable cell strings of a memory cell array 410 to be selected or unselected independently for every mat.

In some embodiments, switch circuit 421a comprises multiple switch units SW1 and SW2 each corresponding to mats. For example, the first switch unit SW1 may control string selection lines SSL1a, SSL1b, SSL1c, and SSL1d connected with a first mat 411 (See, e.g., FIG. 6), and second switch unit SW2 controls string selection lines SSL2a, SSL2b, SSL2c, and SSL2d connected with a second mat 412 (See, e.g., FIG. 6)

Although FIG. 7 illustrates an example where string selection voltage generator 421b generates the selection voltage and the non-selection voltage, the inventive concept is not limited thereto. For example, the selection voltage and the non-selection voltage can be generated by a voltage generator 450 for generating word line voltages. Voltage generator 450 provides the selection voltage and the non-selection voltage to switch circuit 421a through lines. In this case, string selection controller 421 does not include string selection voltage generator 421b.

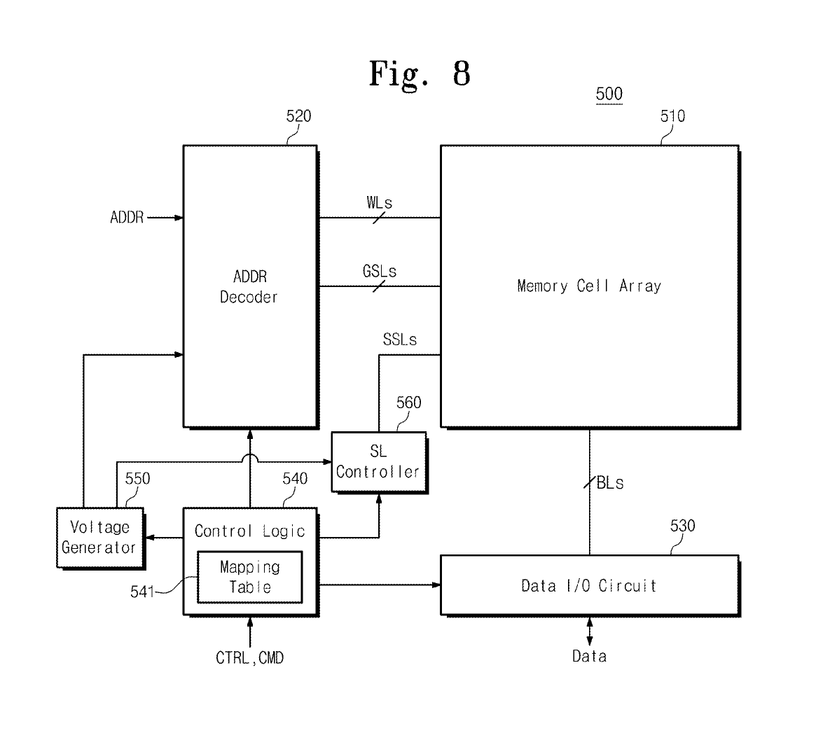

FIG. 8 is a block diagram illustrating a nonvolatile memory device according to another embodiment of the inventive concept.

Referring to FIG. 8, a nonvolatile memory device 500 comprises a memory cell array 510, an address decoder 520, a data input/output circuit 530, control logic 540, a voltage generator 550, and a string selection controller 560.

Control logic 540 controls string selection controller 560, and voltage generator 550 generates a selection or non-selection voltage and provides it to string selection controller 560.

Address decoder 520 provides word line voltages to memory cell array 510 through word lines WLs. Address decoder 520 controls ground selection transistors in cell strings of memory cell array 510 through ground selection lines GSL.

String selection controller 560 controls string selection lines SSLs under control of control logic 540. At this time, each of string selection lines SSLs may be exclusively connected with one of multiple mats of memory cell array 510. String selection controller 560 selects or unselects cell strings of memory cell array 510 independently for every mat through string selection lines SSLs.

String selection controller 560 selectively provides a selection voltage as a string selection signal to string selection lines SSLs to select at least one cell string of memory cell array 510. For example, string selection controller 560 may provide the selection voltage provided from voltage generator 550 to a string selection line, corresponding to a selected cell string, from among string selection lines SSLs. A string selection transistor of the selected cell string may be turned on by the selection voltage applied to the string selection line, and memory cells in the selected cell string may be electrically connected to a corresponding bit line.

String selection controller 560 selectively provides a non-selection voltage as a string selection signal to string selection lines SSLs to unselect at least one cell string of memory cell array 510. For example, string selection controller 560 may provide the non-selection voltage provided from voltage generator 550 to a string selection line, corresponding to an unselected cell string, from among string selection lines SSLs. A string selection transistor of the unselected cell string may be turned off by the non-selection voltage applied to the string selection line, and memory cells in the unselected cell string may be electrically disconnected to a corresponding bit line.

String selection controller 560 may be configured substantially the same as that described with reference to FIGS. 6 and 7. Features 510, 520, 530, 540, and 550 FIG. 8 may be configured substantially the same as corresponding features described with reference to FIG. 4.

As indicated by the above description, nonvolatile memory device 500 may select or unselect cell strings of memory cell array 510 independently for every mat using string selection controller 560. Where a string selection line is defective, only one mat may be influenced by the defective string selection line. Because cell strings in other mats are normally selected, the number of cell strings operating abnormally due to the defective string selection line may be reduced. Also, because string selection signals are independently provided with respect to mats and cell strings are selected independently for every mat, it is easy to control memory cell array 510.

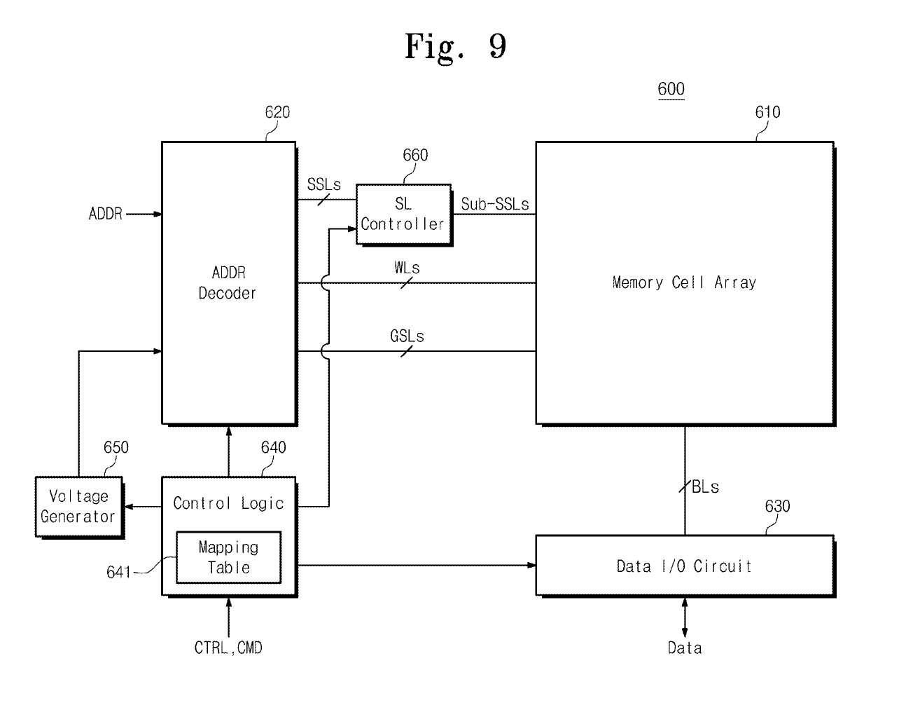

FIG. 9 is a block diagram illustrating a nonvolatile memory device according to still another embodiment of the inventive concept.

Referring to FIG. 9, a nonvolatile memory device 600 comprises a memory cell array 610, an address decoder 620, a data input/output circuit 630, control logic 640, a voltage generator 650, and a string selection controller 660.

Control logic 640 controls string selection controller 660, and voltage generator 650 generates a selection or non-selection voltage to be provided to string selection controller 660.

Address decoder 620 provides word line voltages to memory cell array 610 through word lines WLs. Address decoder 620 controls ground selection transistors in cell strings of memory cell array 510 through ground selection lines GSL. Address decoder 620 provides string selection controller 660 with string selection signals configured to select a cell string of memory cell array 610 through string selection lines SSLs.

Address decoder 620 is connected with cell strings of memory cell array 610 through sub-string selection lines Sub-SSLs. Each of sub-string selection lines Sub-SSLs is exclusively connected with a mat of multiple mats of memory cell array 610. String selection controller 660 selectively provides sub-string selection lines Sub-SSLs with string selection signals provided from address decoder 620 under control of control logic 640. For example, string selection controller 660 may comprise switches configured to selectively connect string selection lines SSLs to sub-string selection lines Sub-SSLs. String selection controller 660 selectively transfers string selection signals provided through string selection lines SSLs to sub-string selection lines Sub-SSLs using the switches.

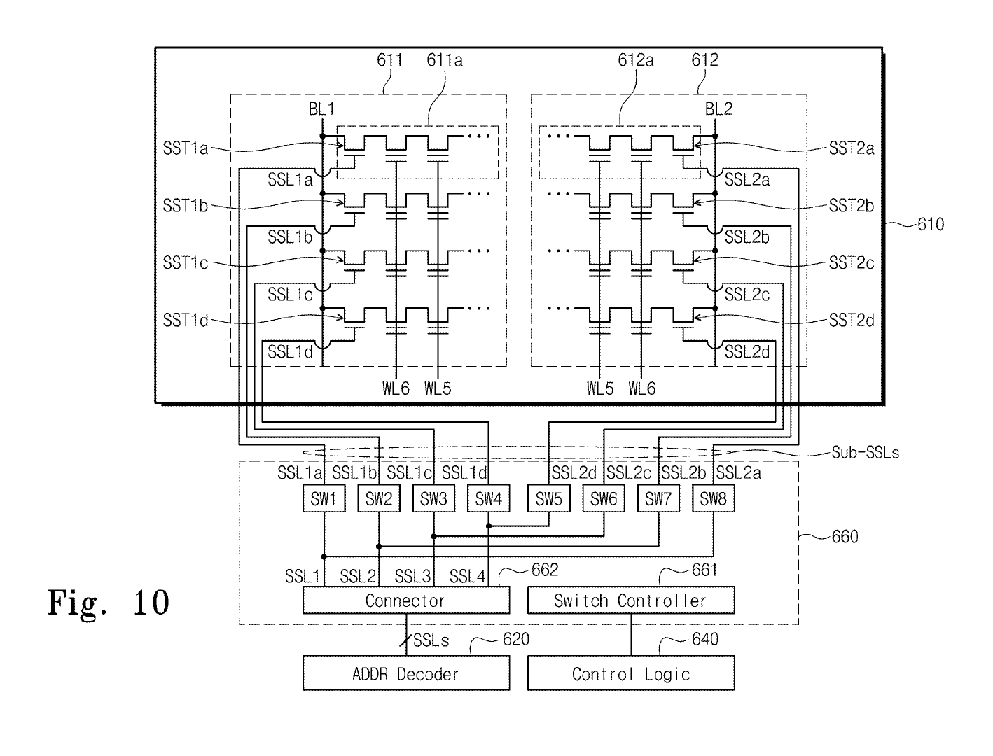

In some embodiments, string selection controller 660 performs control operations such that cell strings of memory cell array 610 are selected or unselected independently for every mat. This will be more fully described with reference to FIG. 10.

Features 610, 620, 630, 640, and 650 not described with reference to FIG. 9 may be substantially the same as corresponding features described with reference to FIG. 4.

As indicated by the above description, each of sub-string selection lines Sub-SSLs of nonvolatile memory device 600 may be exclusively connected only with one mat. Nonvolatile memory device 600 may select or unselect cell strings of memory cell array 610 independently for every mat using string selection controller 660. Where a sub-string selection line is defective, only a mat may be influenced by the defective sub-string selection line. Because cell strings in another mat are normally selected, the number of cell strings operating abnormally due to the defective string selection line may be reduced. Also, because string selection signals are independently provided with respect to mats and cell strings are selected independently for every mat, it is easy to control memory cell array 610.

FIG. 10 is a block diagram illustrating a string selection controller according to still another embodiment of the inventive concept. The embodiment of FIG. 10 is a more specific example of string selection controller 600 of FIG. 9.

Referring to FIG. 10, address decoder 620 is connected to string selection controller 660 through string selection lines SSLs. Address decoder 620 provides string selection signals through string selection lines SSLs. Here, a string selection signal may be a selection voltage or a non-selection voltage.

Control logic 640 controls operations of string selection controller 660. For example, control logic 640 may control switches SW1 to SW8 through a switch controller 661 in string selection controller 660. Memory cell array 610 may include multiple mats 611 and 612 each having multiple cell strings. Memory cell array 610 may be configured substantially the same as a memory cell array 410 of FIG. 6.

String selection controller 660 comprises multiple switches SW1 to SW8, a connector 662, and a switch controller 661. Connector 662 connects string selection lines SSLs to switches SW1 to SW8. In some embodiments, connector 662 connects multiple switches to a string selection line. For example, a first string selection line SSL1 of multiple string selection lines may be connected to first and eighth switches SW1 and SW8. A second string selection line SSL2 of the string selection lines may be connected to second and seventh switches SW2 and SW7. Each of string selection lines SSLs may be connected to multiple mats 611 and 612 of memory cell array 610 through the switches SW1 to SW8.

One ends of switches SW1 to SW8 may be connected to sub-string selection lines Sub-SSLs, respectively. Sub-string selection lines Sub-SSLs may comprise sub-string selection lines SL1a, SSL1b, SSL1c, SSL1d, SSL2a, SSL2b, SSL2c, and SSL2d exclusively connected with a mat of first and second mats 611 and 612.

Switches SW1 to SW8 selectively connect string selection lines SSLs to sub-string selection lines Sub-SSLs. For example, where first switch SW1 is turned on, first string selection lines SSL1 is connected to first sub-string selection lines SSL1a. On the other hand, where first switch SW1 is turned off, first string selection lines SSL1 may be disconnected from first sub-string selection lines SSL1a.

Similarly, where eighth switch SW8 is turned on, first string selection lines SSL1 may be connected to an eighth sub-string selection lines SSL2a. On the other hand, where first switch SW1 is turned off, first string selection lines SSL1 may be disconnected from eighth sub-string selection lines SSL2a.

Where first switch SW1 is turned on, first string selection lines SSL1 may be connected to first sub-string selection lines SSL1a. A string selection signal provided through first string selection line SSL1 may be transferred to first sub-string selection lines SSL1a. The string selection signal provided to first sub-string selection lines SSL1a may be applied to a gate of a first string selection transistor SST1a connected with first sub-string selection lines SSL1a. At this time, if the string selection signal is a selection voltage signal, first string selection transistor SST1a may be turned on. That is, a first cell string 611a may be selected. If the string selection signal is a non-selection voltage signal, first string selection transistor SST1a may be turned off. That is, first cell string 611a may not be selected.

Where first switch SW1 is turned off, first string selection lines SSL1 may be disconnected from first sub-string selection lines SSL1a. The string selection signal provided through first string selection line SSL1 may not be transferred to the first sub-string selection lines SSL1a. Thus, first string selection line SSL1 may not affect selection or non-selection of first string 611a.

Second to eighth switches SW2 to SW8 may operate the same as the above-described operation. For example, where eighth switch SW8 is turned on, first string selection lines SSL1 may be connected to eighth sub-string selection lines SSL2a. A string selection signal may be transferred to eighth sub-string selection lines SSL2a. Where eighth switch SW8 is turned off, first string selection lines SSL1 is disconnected from eighth sub-string selection lines SSL2a, and a string selection signal is not transferred to the eighth sub-string selection lines SSL2a.

String selection controller 660 controls switches SW1 to SW8 to be turned on or off independently. Thus, a string selection line may be independently connected to or disconnected from each of multiple sub-string selection lines. A string selection signal provided from a string selection line may be independently provided to each of the sub-string selection lines.

For example, string selection line SSL1 may be connected to first sub-string selection line SSL1a through first switch SW1. Also, string selection line SSL1 may be connected to eighth sub-string selection line SSL2a through eighth switch SW8. Because first and eighth switches SW1 and SW8 are independently turned on or off, string selection line SSL1 may be independently connected to or disconnected from first or eighth sub-string selection line SSL1a or SSL2a.

Each of mats 611 and 612 may be connected with multiple bit lines. In other words, although FIG. 10 illustrates an example where each of mats 611 and 612 is connected with a bit line, the inventive concept is not limited thereto. For example, each of mats 611 and 612 may be connected with two or more bit lines. The greater the number of bit lines connected with each mat, the greater the number of cell strings connected with a sub-string selection line. For example, where first mat 611 is connected with first bit line BL1 and a second bit lien (not shown), sub-string selection line SSL1a may be simultaneously connected to a cell string 61 la connected to first bit line BL1 and another cell string (not shown) connected to the second bit line. In this case, if a selection voltage is applied to the sub-string selection line SSL1a, two cell strings may be simultaneously selected.

FIG. 11 is a block diagram illustrating a control method for a nonvolatile memory device in which a string selection controller selects a normal cell string rather than a defective cell string, according to an embodiment of the inventive concept.

Referring to FIG. 11, a nonvolatile memory device 700 comprises a memory cell array 710, a string selection controller 720, and control logic 730. Although not shown in FIG. 11, nonvolatile memory device 700 may further comprise an address decoder, a data input/output circuit, and a voltage generator. A control method described with reference to FIG. 11 may be applied to nonvolatile memory devices according to embodiments of the inventive concept.

Memory cell array 710 comprises multiple mats 711 and 712. A first mat 711 comprises multiple cell strings CS1A, CS2A, CS3A, and CS4A, and a second mat 712 comprises multiple cell strings CS1B, CS2B, CS3B, and CS4B. mats 711 and 712. Cell strings CS1A, CS2A, CS3A, CS4A, CS1B, CS2B, CS3B, and CS4B may be configured substantially the same as corresponding features described with reference to FIGS. 3, 4, 6, and 10.

In a program operation, control logic 730 may refer to a mapping table 731 which includes defect information of string selection lines (or, sub-string selection lines) connected with respective cell strings. The defect information of string selection lines may indicate whether a string selection line is defective. Where a defective string selection line is detected, control logic 730 controls string selection controller 720 such that a selection line is selected rather than the defective string selection line.

For example, it is assumed that a string selection line SSL2a corresponding to a cell string CS2A is defective. Where data is sequentially or simultaneously programmed in cell strings CS1A, CS2A, CS3A, and CS4A of first mat 711, control logic 730 prepares to program cell string CS2A. However, because string selection line SSL2a corresponding to cell string CS2A is defective, it is impossible to select cell string CS2A properly in a program operation. Thus, prior to a program operation, control logic 730 may determine whether string selection line SSL2a is defective, based on mapping table 730. If string selection line SSL2a is determined to be defective, control logic 730 may control string selection controller 720 such that a normal string selection line (e.g., SSL4b) is selected rather than the defective string selection line SSL2a. In this case, data programmed in cell string CS2A may be programmed in a cell string CS4B of second mat 712.

String selection controller 720 selects or unselects cell strings CS1A, CS2A, CS3A, CS4A, CS1B, CS2B, CS3B, and CS4B independently for every mat under control of control logic 730. String selection controller 720 may be one of string selection controllers 421, 560, and 660 according to embodiments of the inventive concept.

As indicated by the above description, although a part of string selection lines is defective, a defective string selection line may be replaced with a normal string selection line. This may improve the reliability of nonvolatile memory device 700.

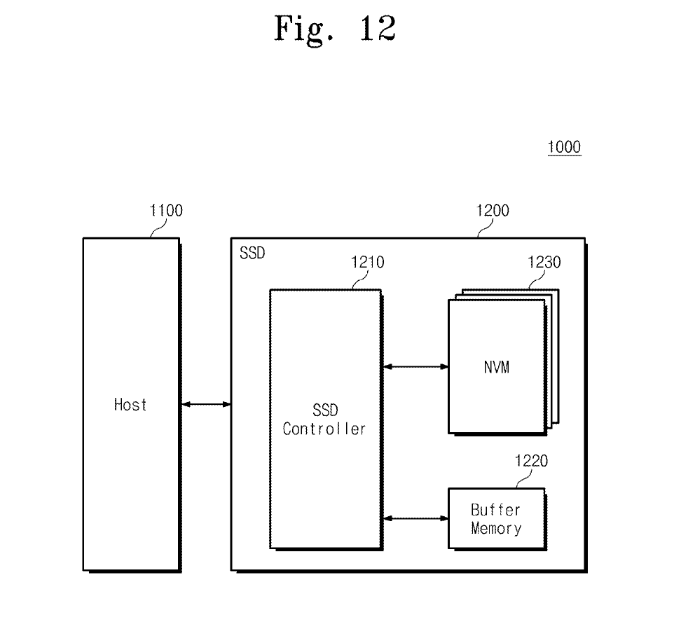

FIG. 12 is a block diagram illustrating an SSD according to an embodiment of the inventive concept.

Referring to FIG. 12, an SSD 1000 comprises an SSD controller 1210, a buffer memory 1220, and a nonvolatile memory device 1230.

SSD controller 1210 provides physical interconnection between a host 1100 and SSD 1200. SSD controller 1210 provides an interface with SSD 1200 corresponding to a bus format of host 1100. In particular, SSD controller 1210 decodes a command provided from host 1100 to access nonvolatile memory device 1230 based on the decoding result. The bus format of host 1100 may include Universal Serial Bus (USB), Small Computer System Interface (SCSI), PCI express, ATA, Parallel ATA (PATA), Serial ATA (SATA), Serial Attached SCSI (SAS), and so on.

Buffer memory 1220 temporarily stores write data provided from host 1100 or data read out from nonvolatile memory device 1230. Where data existing in nonvolatile memory device 1230 is cached, at a read request of host 1100, buffer memory 1220 may support a cache function to provide cached data directly to host 1100. Typically, a data transfer speed of a bus format (e.g., SATA or SAS) of host 1100 may be higher than that of a memory channel of SSD 1200. That is, where an interface speed of host 1100 is remarkably fast, lowering of the performance due to a speed difference may be reduced by providing buffer memory 1220 having a large storage capacity.

Buffer memory 1220 may be formed of a synchronous DRAM to provide sufficient buffering to SSD 1200 used as an auxiliary mass storage device. However, buffer memory 1220 is not limited to this disclosure.

Nonvolatile memory device 1230 may be provided as storage medium of SSD 1200. For example, nonvolatile memory device 1230 may be formed of a vertical NAND flash memory device having a mass storage capacity. Nonvolatile memory device 1230 may be formed of multiple memory devices. In this case, the memory devices may be connected to SSD controller 1210 by a channel unit, respectively. As storage medium, nonvolatile memory device 1230 may be formed of a NAND flash memory. However, nonvolatile memory device 1230 is not limited to a NAND flash memory device. For example, a storage medium of SSD 1200 can be formed of a PRAM, an MRAM, a ReRAM, a FRAM, a NOR flash memory, and the like. Further, the inventive concept may be applied to a memory system which uses different types of memory devices together. Nonvolatile memory device 1230 may be configured substantially the same as that described with reference to FIG. 5, 8 or 9.

In SSD 1200, SSD controller 1210 may enable cell strings of nonvolatile memory device 1230 to be selected or unselected independently for every mat. With this architecture, SSD 1200 may minimize the number of unusable cell strings when a string selection line is defective.

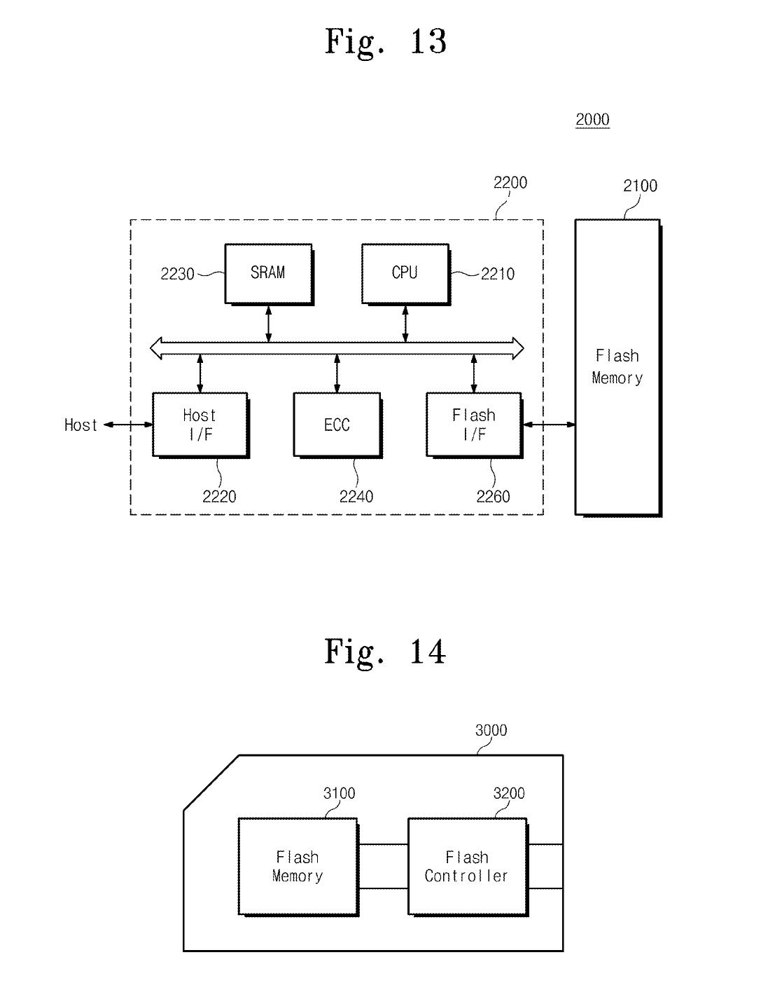

FIG. 13 is a block diagram illustrating a data storage device, according to an embodiment of the inventive concept.

Referring to FIG. 13, a data storage device 2000 according to the inventive concept may include a memory controller 2200 and a nonvolatile memory 2100. Nonvolatile memory 2100 may be configured substantially the same as one of nonvolatile memory devices described with reference to FIGS. 5, 8 and 9. Memory controller 2200 may be configured to control nonvolatile memory 2100.

An SRAM 2230 may be used as a working memory of a CPU 2210. A host interface 2220 may have a data exchange protocol of a host connected with data storage device 2000. An ECC 2240 of memory controller 2200 may detect and correct an error of data read from nonvolatile memory 2100. A memory interface 2260 may interface with nonvolatile memory 2100 of the inventive concept. CPU 2210 may control an overall operation for data exchange of memory controller 2200. Although not shown in FIG. 13, data storage device 2000 may further include a ROM which stores code data for an interface with the host.

Memory controller 2100 may be configured to communicate with an external device (e.g., a host) using one of various interface protocols such as USB, MMC, PCI-E, SAS, SATA, PATA, SCSI, ESDI, IDE, and so on.

In data storage device 2000, memory controller 2200 may enable cell strings of nonvolatile memory device 2100 to be selected or unselected every mat. With this architecture, data storage device 2000 may minimize the number of unusable cell strings when a string selection line is defective.

Data storage device 2000 may be applied to a computer, a portable computer, an UMPC (Ultra Mobile PC), a workstation, a net-book, a PDA, a web tablet, a wireless phone, a mobile phone, a smart phone, a digital camera, a digital audio recorder, a digital audio player, a digital picture recorder, a digital picture player, a digital video recorder, a digital video player, a device capable of transmitting and receiving information at a wireless environment, or one of user devices constituting a home network.

FIG. 14 is a block diagram illustrating a memory card according to an embodiment of the inventive concept.

Referring to FIG. 14, a memory card 3000 comprises a flash memory 3100 and a memory controller 3200. Memory controller 3200 controls flash memory 3100 based on control signals provided from an external source.

In memory card 3000, flash memory 3100 may be configured substantially the same as one of nonvolatile memory devices described with reference to FIGS. 5, 8 and 9. Memory controller 3200 enables cell strings of flash memory 3100 to be selected or unselected on a mat by mat basis. With this architecture, memory card 3000 may reduce the number of unusable cell strings where a string selection line is defective.

Memory card 3000 may take the form of a memory card device, an SSD device, a multimedia card device, an SD card, a memory stick device, a hard disk driver, a hybrid drive device, or a USB flash device, for example. Additionally, memory card 3000 may form a card satisfying the industrial standards for use of user devices such as a digital camera, a personal computer, and so on.

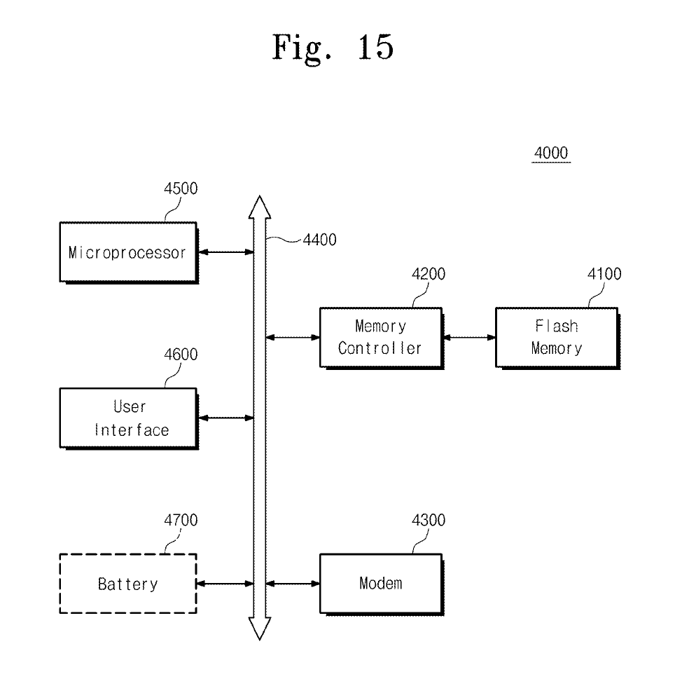

FIG. 15 is a block diagram illustrating a computing system comprising a memory system, according to an embodiment of the inventive concept.

Referring to FIG. 15, a computing system 4000 comprises a flash memory device 4100, a memory controller 4200, a modem 4300 such as a baseband chipset, a microprocessor 4500, and a user interface 4600. Memory controller 4200, modem 4300, microprocessor 4500, and user interface 4600 are electrically connected to a bus 4400.

In computing system 4000, flash memory device 4100 may be configured substantially the same as one of nonvolatile memory devices described with reference to FIGS. 1, 8, and 9. In computing system 4000, memory controller 4200 enables cell strings of flash memory device 4100 to be selected or unselected every mat. With this architecture, computing system 4000 may minimize the number of unusable cell strings when a string selection line is defective.

Where computing system 4000 is a mobile device, it may further include a battery 4700 which powers computing system 4000. Although not shown in FIG. 15, computing system 4000 may further include an application chipset, a camera image processor (CIS), a mobile DRAM, and the like. Flash memory device 4100 and memory controller 4200 may constitute an SSD which uses a nonvolatile memory to store data, for example.

A nonvolatile memory device and/or a memory controller may be packed by one selected from various types of packages such as Package on Package (PoP), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), and the like.

The foregoing is illustrative of embodiments and is not to be construed as limiting thereof. Although a few embodiments have been described, those skilled in the art will readily appreciate that many modifications are possible in the embodiments without departing from the scope of the inventive concept. Accordingly, all such modifications are intended to be included within the scope of the inventive concept as defined in the claims.

What is claimed is:

1. A nonvolatile memory device, comprising:
a three-dimensional (3D) memory cell array comprising multiple mats corresponding to different bit lines, each of the mats comprising multiple memory blocks, each of the memory blocks comprising multiple cell strings disposed perpendicular to a substrate and multiple string selection lines configured to select or unselect the cell strings, and each of the cell strings comprising at least one ground selection transistor, multiple memory cells, and at least one string selection transistor stacked in a direction perpendicular to the substrate; and
a string selection controller electrically connected to the mats through the string selection lines and configured to provide multiple string selection signals respectively corresponding to the string selection lines,
wherein each of the string selection lines is connected with only one of the mats and the string selection signals are controlled independent from one another to independently select or unselect cell strings of different mats.

2. The nonvolatile memory device of claim 1, wherein each of the string selection signals is provided to one or more cell strings of the cell strings through a corresponding string selection line, and wherein
the one or more cell strings are selected or unselected independently from other cell strings according to whether a designated string selection signal provided to the one or more cell strings has a selection voltage.

3. The nonvolatile memory device of claim 2, wherein where the designated string selection signal has a selection voltage, a voltage level of the designated string selection signal has a logic high level.

4. The nonvolatile memory device of claim 2, wherein the designated string selection signal is provided to string selection transistors of the one or more cell strings as a gate voltage.

5. The nonvolatile memory device of claim 2, wherein the designated string selection signal is provided to ground selection transistors of the one or more cell strings as a gate voltage.

6. The nonvolatile memory device of claim 2, further comprising:
a read/write circuit connected to the mats through the different bit lines;
an address decoder connected to the mats through multiple word lines;
a voltage generator configured to generate voltages to be applied to the word lines; and
control logic configured to control the read/write circuit, the string selection controller and the address decoder.

7. The nonvolatile memory device of claim 6, wherein the read/write circuit comprises multiple page buffers respectively corresponding to the mats.

8. The nonvolatile memory device of claim 6, wherein the string selection controller comprises:
a selection voltage generator configured to generate the selection voltage; and
a switch circuit configured to selectively provide the selection voltage to each of the string selection lines.

9. The nonvolatile memory device of claim 8, wherein the string selection controller is disposed in the address decoder.

10. The nonvolatile memory device of claim 6, wherein the string selection controller comprises:
multiple switches configured to selectively provide a selection voltage provided from the address decoder to the string selection lines; and
a switch controller configured to control the switches.

11. The nonvolatile memory device of claim 10, wherein the string selection controller further comprises:
a connector configured to connect the switches and the address decoder.

12. The nonvolatile memory device of claim 6, wherein where data is programmed in the memory cell array, the control logic controls the string selection controller by referring to a mapping table including information on defective string selection lines of the string selection lines, such that the defective string selection line is replaced with another string selection line of the string selection lines.

13. The nonvolatile memory device of claim 12, wherein a mat comprising a cell string connected to the defective string selection line is different from a mat comprising the another string selection line.

14. A memory system, comprising:
a nonvolatile memory device comprising a three-dimensional (3D) memory cell array including multiple mats corresponding to different bit lines, each of the mats comprising multiple memory blocks, each of the memory blocks comprising multiple cell strings disposed perpendicular to a substrate and multiple string selection lines configured to select or unselect the cell strings; and
a memory controller configured to control the nonvolatile memory device such that at least one of the cell strings is independently selected or unselected through multiple string selection lines corresponding to the cell strings,
wherein each of the string selection lines is connected with only one of the mats and the string selection signals are controlled independently from one another to independently select or unselect cell strings of different mats.

15. The memory system of claim 14, wherein the nonvolatile memory device further comprises:
a string selection controller configured to provide a selection voltage to one of the string selection lines such that at least one cell string connected with the one string selection line is independently selected.

16. A nonvolatile memory device, comprising:
a three-dimensional (3D) memory cell array comprising multiple mats corresponding to different bit lines, each of the mats comprising multiple memory blocks each comprising multiple cell strings disposed perpendicular to a substrate, and at least one string selection line or ground selection line configured to select or unselect the cell strings, and each of the cell strings comprising at least one ground selection transistor, multiple memory cells, and at least one string selection transistor stacked in a direction perpendicular to the substrate, the memory cell array further comprising a plurality of word lines connected in common to cell strings of different mats; and
a string selection controller electrically connected to the mats through the string selection lines or the ground selection lines and configured to provide multiple string selection signals respectively corresponding to the string selection lines or ground selection lines,
wherein each of the string selection lines or ground selection lines is connected with only one of the mats and the string selection signals are controlled independent from one another to independently select or unselect cell strings of different mats, and wherein the word lines connected in common to the cells strings of different mats are configured to concurrently select memory cells in the different mats.

17. The nonvolatile memory device of claim 16, wherein each of the ground selection lines is connected with only one of the mats.

18. The nonvolatile memory device of claim 16, wherein each of the string selection signals is provided to one or more cell strings of the cell strings through a corresponding string selection line, and wherein
the one or more cell strings are selected or unselected independently from other cell strings according to whether a designated string selection signal provided to the one or more cell strings has a selection voltage.

19. The nonvolatile memory device of claim 18, wherein where the designated string selection signal has a selection voltage, a voltage level of the designated string selection signal has a logic high level.

20. The nonvolatile memory device of claim 18, wherein the designated string selection signal is provided to string selection transistors of the one or more cell strings as a gate voltage.
